(19) United States
(12) Patent Application Publication
(10) Pub. No.: US 2019/0052059 A1
(43) Pub. Date: Feb. 14, 2019

(54) SURFACE-EMITTING LASER

(71) Applicant: SUMITOMO ELECTRIC INDUSTRIES, LTD., Osaka (JP)

(72) Inventor: Ryosuke Kubota, Yokohama-shi (JP)

(73) Assignee: SUMITOMO ELECTRIC INDUSTRIES, LTD., Osaka (JP)

(21) Appl. No.: 15/945,386

(22) Filed: Apr. 4, 2018

(30) Foreign Application Priority Data
Aug. 9, 2017 (JP) 2017-154220

(51) Int. Cl. H01S 5/187; H01S 5/042; H01S 5/343; H01S 5/183

(52) U.S. Cl. CPC H01S 5/187; H01S 5/0421; H01S 5/0425; H01S 5/34313; H01S 5/028; H01S 5/18352; H01S 5/18347; H01S 5/18308; H01S 2304/04; H01S 5/34353

(57) ABSTRACT

A surface-emitting laser includes a substrate having a principal surface; an active layer provided on the principal surface of the substrate; a first stacked layer provided on the active layer, the first stacked layer serving as a first distributed Bragg reflector; a first contact layer disposed between the active layer and the first stacked layer; a post provided on the principal surface of the substrate, the post including the active layer, the first contact layer, and the first stacked layer, the post having an upper surface, a side surface inclined relative to the substrate principle surface, and a lower end; and a first electrode that contacts the first contact layer at the side surface of the post.

### BACKGROUND OF THE INVENTION

### 1. Field of the Invention

The present invention relates to a surface-emitting laser.

### 2. Description of the Related Art

Japanese Unexamined Patent Application Publication No. 2014-168082 discloses a surface-emitting laser.

### SUMMARY OF THE INVENTION

The surface-emitting laser disclosed in Japanese Unexamined Patent Application Publication No. 2014-168082 has a quadrangular-prism-shaped mesa structure including a contact layer, an upper distributed Bragg reflector (DBR), and an active layer. The contact layer appears from an upper surface of the mesa structure. The surface-emitting laser further includes an electrode that contacts the contact layer at the upper surface of the mesa structure. A carrier (current) injected from the contact layer passes through the upper DBR and reaches the active layer. Hence, the distance between the contact layer and the active layer is increased, and the injection efficiency of the carrier (current) into the active layer is decreased. Further, other problems may arise, for example, the electrical resistance of the surface-emitting laser is increased.

A surface-emitting laser according to an aspect of the present invention includes a substrate having a principal surface; an active layer provided on the principal surface of the substrate; a first stacked layer provided on the active layer, the first stacked layer serving as a first distributed Bragg reflector; a first contact layer disposed between the active layer and the first stacked layer; a post provided on the principal surface of the substrate, the post including the active layer, the first contact layer, and the first stacked layer, the post having an upper surface, a side surface, and a lower end; and a first electrode that contacts the first contact layer at the side surface of the post.

The above-described object and other objects, features, and advantages according to the present invention will be more easily understood from the following detailed description on preferred embodiments according to the present invention with reference to the accompanying drawings.

### BRIEF DESCRIPTION OF THE DRAWINGS

FIG. 1 is a partly cutaway view schematically illustrating a vertical cavity surface-emitting laser according to an embodiment.

FIG. 2 is a partly cutaway view schematically illustrating the vertical cavity surface-emitting laser according to the embodiment.

FIGS. 3A and 3B schematically illustrate a layer structure around a first contact layer in the surface-emitting laser illustrated in FIGS. 1 and 2.

FIGS. 4A and 4B schematically illustrate major steps in a method of fabricating the surface-emitting laser according to the embodiment.

FIGS. 5A and 5B schematically illustrate major steps in the method of fabricating the surface-emitting laser according to the embodiment.

FIGS. 6A and 6B schematically illustrate major steps in the method of fabricating the surface-emitting laser according to the embodiment.

FIGS. 7A and 7B schematically illustrate major steps in the method of fabricating the surface-emitting laser according to the embodiment.

FIGS. 8A and 8B schematically illustrate major steps in the method of fabricating the surface-emitting laser according to the embodiment.

FIGS. 9A and 9B schematically illustrate major steps in the method of fabricating the surface-emitting laser according to the embodiment.

FIGS. 10A and 10B schematically illustrate major steps in the method of fabricating the surface-emitting laser according to the embodiment.

### DESCRIPTION OF THE PREFERRED EMBODIMENTS

Some specific embodiments will be described below.

A surface-emitting laser according to an embodiment includes (a) a substrate having a principal surface; (b) an active layer provided on the principal surface of the substrate; (c) a first stacked layer provided on the active layer, the first stacked layer serving as a first distributed Bragg reflector; (d) a first contact layer disposed between the active layer and the first stacked layer; (e) a post provided on the principal surface of the substrate, the post including the active layer, the first contact layer, and the first stacked layer, the post having an upper surface, a side surface, and a lower end; and (f) a first electrode that contacts the first contact layer at the side surface of the post.

According to the surface-emitting laser, the active layer, the first contact layer, and the first stacked layer are stacked in that order on the principal surface of the substrate. Also, the post including the active layer, the first contact layer, and the first stacked layer has the side surface that contacts the first electrode. A carrier (current) injected from the first electrode passes through the first contact layer and reaches the active layer. Hence, a carrier (current) injected from the first contact layer reaches the active layer without passing through the first stacked layer.

The surface-emitting laser according to an embodiment may further include an intermediate stacked layer provided between the first contact layer and the active layer. The first contact layer may have a side surface that constitutes a portion of the side surface of the post. In addition, the side surface of the first contact layer may extend from an edge at a boundary between the first contact layer and the first stacked layer to an edge at a boundary between the first contact layer and the intermediate stacked layer.

In the surface-emitting laser, the first electrode contacts the side surface of the first contact layer in the post. The current injected from the first electrode passes through the first contact layer and reaches the active layer.

In the surface-emitting laser according an embodiment, the side surface of the post may be widened out in a direction from the upper surface of the post toward the lower end of the post.

In the surface-emitting laser, the first electrode contacts the side surface of the widened-out post. The current injected from the first electrode passes through the first contact layer and reaches the active layer.

The surface-emitting laser according to an embodiment may further include a second stacked layer provided between the substrate and the active layer, the second stacked layer including a second contact layer, the second stacked layer serving as a second distributed Bragg reflector; and a second electrode that contacts the second contact layer. The lower end of the post may be located in the second contact layer.

In the surface-emitting laser, the lower end of the post is located in the second contact layer. Also, the second electrode contacts an upper surface of the second contact layer.

In the surface-emitting laser according to an embodiment, the first stacked layer may contain an undoped semiconductor.

In the surface-emitting laser, the first stacked layer has a low optical absorption loss and high reflectivity as a distributed Bragg reflector.

The findings according to the present invention can be easily understood with regard to the detailed description given below with reference to the exemplarily presented accompanying drawings. Now, a surface-emitting laser and a method of fabricating the surface-emitting laser according to an embodiment are described with reference to the accompanying drawings. The same reference sign is applied to the same part if possible.

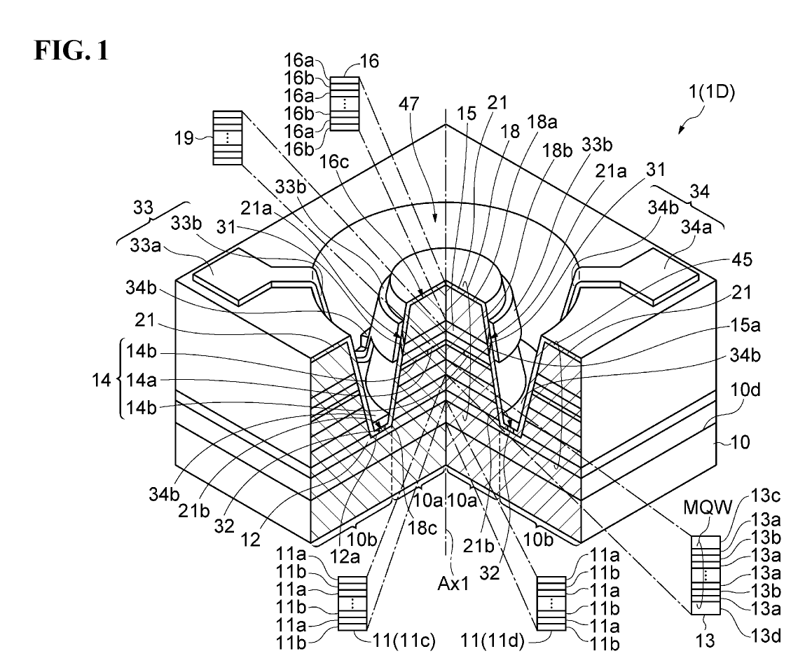

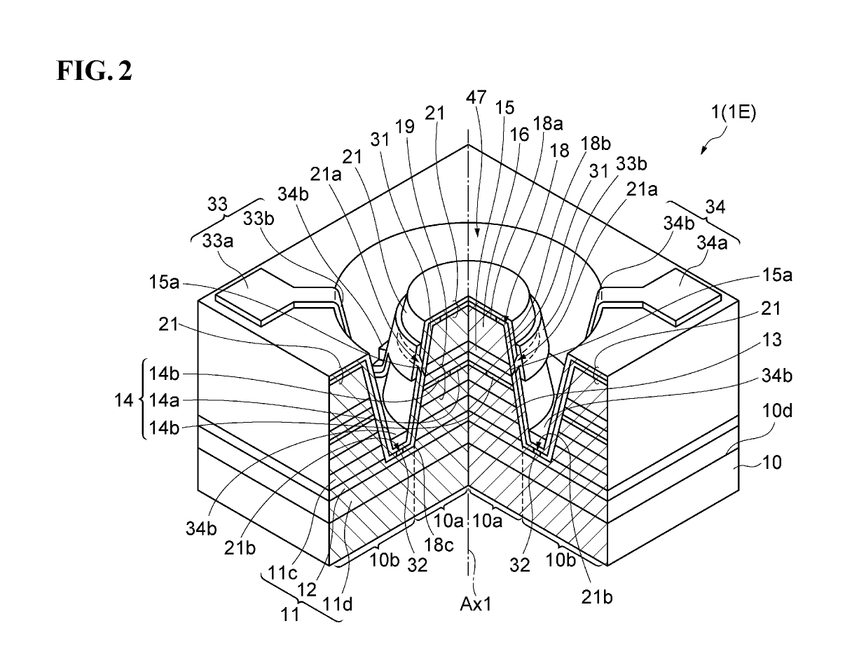

FIG. 1 is a partly cutaway view schematically illustrating a vertical cavity surface-emitting laser according to an embodiment. FIG. 2 is also a partly cutaway views schematically illustrating a vertical cavity surface-emitting laser according to another embodiment. Referring to FIGS. 1 and 2, a surface-emitting laser 1 (1D, 1E) includes a substrate 10, an active layer 13, a first contact layer 15, and a first stacked layer 16. The active layer 13, the first contact layer 15, and the first stacked layer 16 are stacked in that order on a principal surface 10d of the substrate 10. The first stacked layer 16 is provided for forming a first distributed Bragg reflector. With this configuration, a carrier (current) injected from the first contact layer 15 directly flows to the active layer 13 without passing through the first stacked layer 16.

The active layer 13, the first contact layer 15, and the first stacked layer 16 constitute a post 18. The post 18 has an upper surface 18a, a side surface 18b, and a lower end 18c. The post 18 is provided on the principal surface 10d of the substrate 10. The surface-emitting laser 1 includes a first electrode 31. The first electrode 31 contacts the first contact layer 15 at the side surface 18b of the post 18. In the surface-emitting laser 1, the post 18 includes the active layer 13, the first contact layer 15, and the first stacked layer 16. The post has the side surface 18b that contacts the first electrode 31. The current injected from the first electrode 31 passes through the first contact layer 15 and reaches the active layer 13. The substrate 10 has a first region 10a and a second region 10b surrounding the first region 10a. The post 18 is disposed on the first region 10a of the substrate 10.

The first stacked layer 16 has an upper surface 16c that appears at the upper surface 18a of the post 18. The first stacked layer 16 has a first layer 16a and a second layer 16b. The first layer 16a and the second layer 16b are alternately stacked in the direction of a first axis Ax1 so as to function as a distributed Bragg reflector. The first axis Ax1 extends in a direction perpendicular to the principal surface 10d of the substrate 10. The first layer 16a and the second layer 16b have refractive indices different from each other. In the embodiment, each of the first layer 16a and the second layer 16b has a side surface, and the side surface constitutes a portion of the side surface 18b of the post 18.

The surface-emitting laser 1 further includes an intermediate stacked layer 19 provided between the active layer 13 and the first contact layer 15. The first contact layer 15 has a side surface 15a that constitutes a portion of the side surface 18b of the post 18. The side surface 15a of the first contact layer 15 extends from an edge at the boundary between the first contact layer 15 and the first stacked layer 16 to an edge at the boundary between the first contact layer 15 and the intermediate stacked layer 19. In the surface-emitting laser 1, the first electrode 31 contacts the side surface 15a of the first contact layer 15 at the post 18. The current injected from the first electrode 31 passes through the first contact layer 15 and reaches the active layer 13. The intermediate stacked layer 19 is located in the path of the current. The intermediate stacked layer 19 has conductivity, and has a lower dopant concentration than the dopant concentration of the first contact layer 15.

The intermediate stacked layer 19 has an upper semiconductor layer that contacts the first contact layer 15. The first stacked layer 16 has a lower semiconductor layer that contacts the first contact layer 15. The first contact layer 15 has a higher dopant concentration than the dopant concentration of the upper semiconductor layer of the intermediate stacked layer 19. Also, the first contact layer 15 has a higher dopant concentration than the dopant concentration of the lower semiconductor layer of the first stacked layer 16. In the embodiment, at least an upper portion of the first stacked layer 16 contains an undoped semiconductor. Alternatively, the first stacked layer 16 may be entirely made of an undoped semiconductor. Since the first stacked layer 16 contains the undoped semiconductor, the first stacked layer 16 has a low optical absorption loss. The upper distributed Bragg reflector constituted by the first stacked layer 16 is effective for increasing the optical power. For example, the distributed Bragg reflector made of the undoped semiconductor according to the embodiment increases the optical power by about 2% as compared with a distributed Bragg reflector having a p-doping concentration of 1×10¹⁸ cm⁻³ and a layer thickness of 400 nm.

In the embodiment, the intermediate stacked layer 19 includes a current confinement structure 14. The current confinement structure 14 has a semiconductor region 14a made of a semiconductor containing aluminum as a III group constituent element, and a dielectric region 14b containing an aluminum oxide. The current confinement structure 14 is provided between the active layer 13 and the first contact layer 15, and adjusts the distribution of a carrier (current) flow in the post 18. If required, the intermediate stacked layer 19 may include the first layer 16a and the second layer 16b that are alternately stacked so as to function as a distributed Bragg reflector like the first stacked layer 16.

The surface-emitting laser 1 further includes a second stacked layer 11 for forming a second distributed Bragg reflector and a second electrode 32. The second stacked layer 11 is provided between the substrate 10 and the active layer 13. The post 18 includes the second stacked layer 11 in addition to the active layer 13. The second stacked layer 11 includes a second contact layer 12, a first portion 11c, and a second portion 11d. In the embodiment, the second contact layer 12 is provided between the first portion 11c and the second portion 11d. The lower end 18c of the post 18 is located in the second contact layer 12. The first portion 11c of the second stacked layer 11 is provided in the post 18. The second contact layer 12 includes an upper portion and a lower portion. The upper portion of the second contact layer 12 is provided in the post 18. The lower portion of the second contact layer 12 is provided above the first region 10a and the second region 10b of the substrate 10. The first portion 11c is provided above the first region 10a of the substrate 10. The second portion 11d extends over the first region 10a and the second region 10b of the substrate 10. The first portion 11c and the second portion 11d each have a first layer 11a and a second layer 11b. The first layer 11a and the second layer 11b are stacked in the direction of the first axis Ax1 so as to function as a distributed Bragg reflector. The first layer 11a and the second layer 11b have refractive indices different from each other. In the embodiment, each of the first layer 16a and the second layer 16b has a side surface, and the side surface constitutes a portion of the side surface 18b of the post 18.

In the surface-emitting laser 1, the lower end 18c of the post 18 is located in the second contact layer 12. The second electrode 32 contacts an upper surface of the second contact layer 12. As described above, the upper portion of the second contact layer 12 is provided in the post 18. Also, the lower portion of the second contact layer 12 is provided over the first region 10a and the second region 10b of the substrate 10.

The surface-emitting laser 1 includes an insulating layer 21 that covers the post 18. The insulating layer 21 covers the side surface 18b and the upper surface 18a of the post 18. The insulating layer 21 has a first opening 21a that reaches the side surface 15a of the first contact layer 15. The first opening 21a has, for example, a closed shape along the side surface 15a of the first contact layer 15. The first opening 21a is separated from a side surface of the active layer 13 in the post 18. However, the shape of the first opening 21a is not limited to the shape located only in the area of the side surface 15a of the first contact layer 15. The first electrode 31 contacts a semiconductor side surface of the post 18. Specifically, the first electrode 31 contacts the side surface 15a of the first contact layer 15 and an area adjacent thereto.

The insulating layer 21 has a second opening 21b that reaches the second contact layer 12. The second opening 21b is located above the second region 10b of the substrate 10. The second opening 21b extends along, for example, a loop-shaped curve, and formed in an upper surface 12a of the second contact layer 12. The second opening 21b is separated from the side surface of the active layer 13 in the post 18. The second electrode 32 contacts the upper surface 12a of the second contact layer 12 through the second opening 21b, on an outer side of the post 18.

The active layer 13 includes, for example, a multi quantum well (MQW) structure. The MQW includes a well layer 13a and a barrier layer 13b that are alternately stacked. The active layer 13 includes an upper spacer layer 13c of an undoped semiconductor located between the MQW structure and the intermediate stacked layer 19, and a lower spacer layer 13d of an undoped semiconductor located between the second stacked layer 11 and the MQW structure. Regarding the semiconductor in the post 18, for example, a p-type (n-type) dopant is doped in the semiconductor provided above the active layer 13. For example, a n-type (p-type) dopant is doped in the semiconductor provided below the active layer 13.

The surface-emitting laser 1 includes a first conductor 33 and a second conductor 34. The first conductor 33 includes a first pad electrode 33a located on the insulating layer 21, and a first wiring conductor 33b that connects the first pad electrode 33a to the first electrode 31. The second conductor 34 includes a second pad electrode 34a located on the insulating layer 21, and a second wiring conductor 34b that connects the second pad electrode 34a to the second electrode 32.

In the embodiment, the surface-emitting laser 1 has a terrace 45 and a groove 47. The groove 47 isolates the post 18 from the terrace 45. The first pad electrode 33a and the second pad electrode 34a are provided on the terrace 45. The second opening 21b is located at the bottom of the groove 47. The first wiring conductor 33b extends along the first electrode 31 in the first opening 21a on the side surface 18b of the post 18. In addition, the first wiring conductor 33b extends across the groove 47, and connects the first electrode 31 to the first pad electrode 33a. The second wiring conductor 34b extends along the second electrode 32 in the second opening 21b at the bottom of the groove 47. In addition, the second wiring conductor 34b extends upward along the side surface of the groove 47, and connects the second electrode 32 to the second pad electrode 34a.

Example of Surface-Emitting Laser 1

### Example of Stacked Semiconductor Layer 51 on Substrate 10

Substrate 10: semi-insulating gallium arsenide (GaAs) substrate
First stacked layer 16: undoped aluminum gallium arsenide (AlGaAs)/AlGaAs super lattice structure, or undoped AlGaAs/GaAs super lattice structure
First contact layer 15: carbon-doped (C-doped) p-type AlGaAs, C-doped p-type GaAs, zinc-doped (Zn-doped) p-type AlGaAs, or Zn-doped p-type GaAs

### Current Confinement Structure 14

Semiconductor region 14a: aluminum-containing (Al-containing) semiconductor layer, for example, AlGaAs, Al content=0.98
Dielectric region 14b: aluminum oxide
Second contact layer 12: silicon-doped (Si-doped) n-type AlGaAs, Si-doped n-type GaAs

### Second Stacked Layer 11

First portion 11c: Si-doped AlGaAs/AlGaAs super lattice structure, or Si-doped GaAs/AlGaAs super lattice structure
Second portion 11d: undoped AlGaAs/AlGaAs super lattice structure, or undoped GaAs/AlGaAs super lattice structure
Active layer 13: undoped indium gallium arsenide (InGaAs)/GaAs multi quantum well

### (MQW) Structure

Insulating layer 21: silicon-based inorganic insulator, specifically, silicon nitride (SiN) or silicon oxynitride (SiON)

Referring to FIG. 1, in the surface-emitting laser 1D, the first opening 21a is located on the side surface 15a of the first contact layer 15 at the side surface 18b of the post 18. The first electrode 31 contacts the side surface 15a of the first contact layer 15 through the first opening 21a. The insulating layer 21 covers the entire upper surface and the almost entire side surface of the first stacked layer 16.

Referring to FIG. 2, in the surface-emitting laser 1E, the first opening 21a is located on the side surface 15a of the first contact layer 15 and the side surface of the first stacked layer 16 that constitute a portion of the side surface 18b of the post 18. The first electrode 31 contacts the side surface 15a of the first contact layer 15 through the first opening 21a. The insulating layer 21 partly covers the upper surface of the first stacked layer 16.

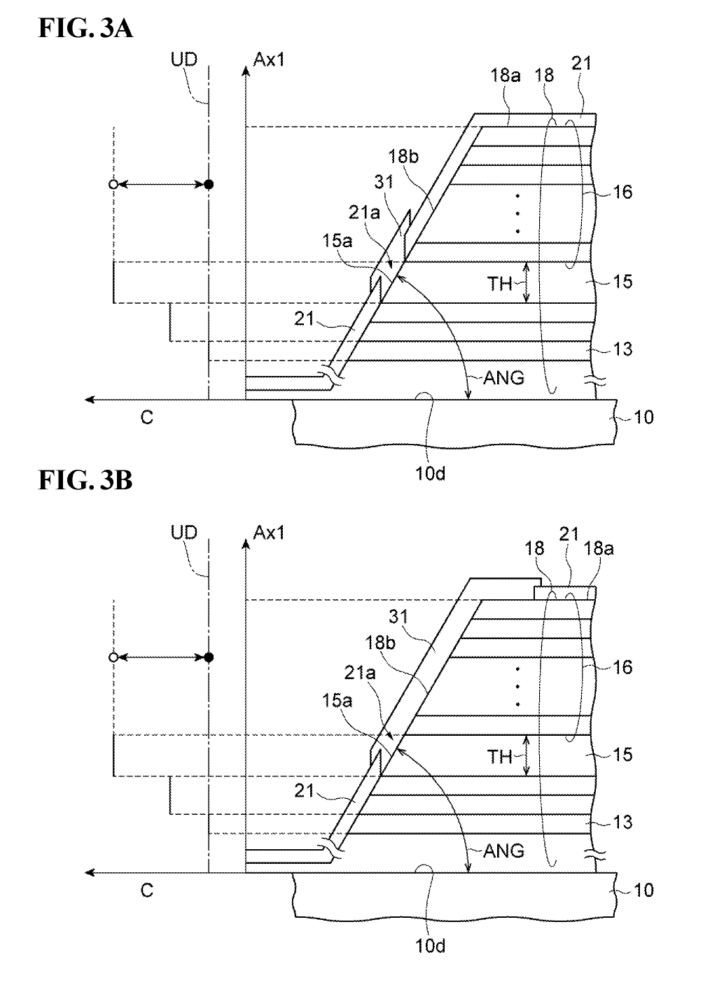

FIGS. 3A and 3B each schematically illustrate the layer structure around the first contact layer in the surface-emitting laser 1 (1D, 1E). The side surface 18b of the post 18 is widened out in a direction from the upper surface 18a of the post 18 toward the lower end 18c of the post 18. The surface-emitting laser 1 includes the first contact layer 15 that contacts the first electrode 31 on the side surface 18b of the post 18. With the surface-emitting laser 1, the current injected from the first electrode 31 passes through the first contact layer 15 and reaches the active layer 13. The side surface 18b of the post 18 preferably has an inclination angle ANG in a range from 45 to 75 degrees. The inclination angle is an angle defined by a tangent in contact with the side surface 18b of the post 18 and the principal surface 10d of the substrate 10. The tangent is in contact with the side surface of the active layer in the post 18, and extends in a reference plane perpendicular to the principal surface 10d of the substrate 10.

Referring to FIGS. 3A and 3B, a dopant profile in the post 18 is illustrated. “UD” represents an undope level. “C” denotes a dopant concentration. The first contact layer 15 has a higher dopant concentration than the dopant concentration of the upper semiconductor layer of the intermediate stacked layer 19. For example, the first contact layer 15 has a dopant concentration in a range from 1×10¹⁸ to 3×10¹⁹ cm⁻³. The dopant concentration of the first stacked layer 16 is lower than the dopant concentration of the first contact layer 15, or preferably is lower than the dopant concentration of the intermediate stacked layer 19. At least a portion of the first stacked layer 16 is preferably undoped. For example, a dopant is doped in a lower portion of the first stacked layer 16. In contrast, an upper portion of the first stacked layer 16 contains an undoped semiconductor. Alternatively, the first stacked layer 16 may be entirely made of an undoped semiconductor. The dopant concentration of the first contact layer 15 is preferably the highest in the semiconductor in the post 18. In the embodiment, the first contact layer 15 is preferably made of Al_{X}Ga_{1-X}As (X is equal to and greater than 0 and equal to or smaller than 0.5) having a smaller band gap energy than that of ternary AlGaAs in the first stacked layer 16 and the intermediate stacked layer 19. The first contact layer 15 has a thickness TH in a range from 40 to 90 nm.

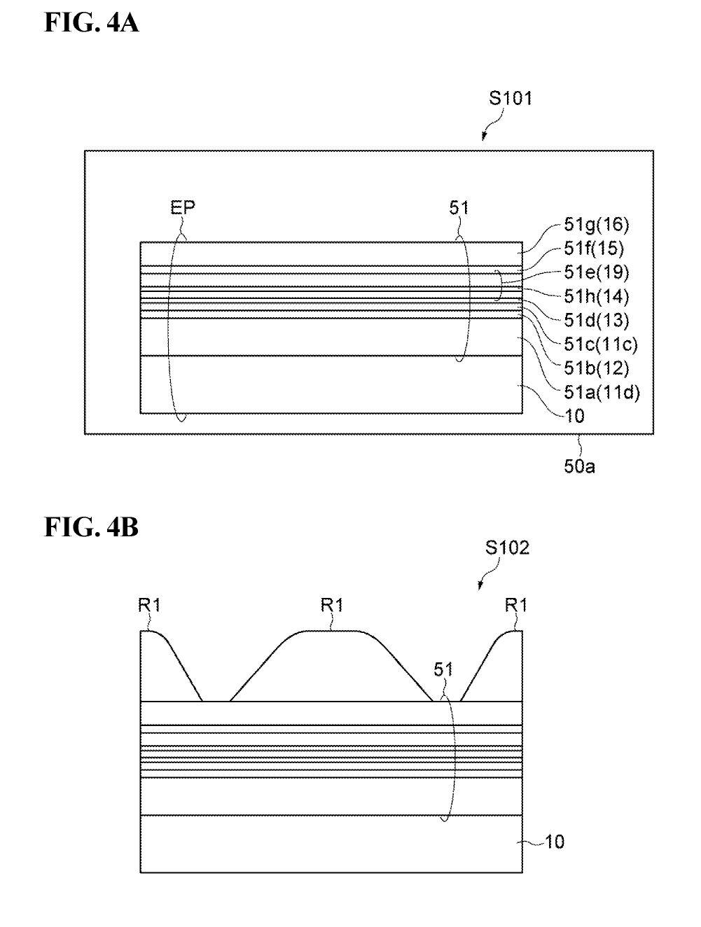

A method of fabricating a surface-emitting laser according to the embodiment is described with reference to FIGS. 4A to 10B. FIGS. 4A to 10B schematically illustrate major steps in the method of fabricating the surface-emitting laser according to the embodiment. In the following description, the reference signs applied to FIGS. 1 and 2 are used if possible for easier understanding.

In step S101, as illustrated in FIG. 4A, a stacked semiconductor layer 51 for forming a surface-emitting laser is grown on a semiconductor substrate 10 in a growth furnace 50a, and hence an epitaxial substrate EP is formed. In the growth of the stacked semiconductor layer 51, a metal-organic vapor phase epitaxy method is used, for example. The stacked semiconductor layer 51 includes a stacked semiconductor layer 51a, a semiconductor layer 51b, stacked semiconductor layers 51c and 51d, a stacked semiconductor layer 51e, a semiconductor layer 51f, and a stacked semiconductor layer 51g. The stacked semiconductor layer 51a, the semiconductor layer 51b, the stacked semiconductor layers 51c and 51d, the stacked semiconductor layer 51e, the semiconductor layer 51f, and the stacked semiconductor layer 51g are provided for forming the second portion 11d of the second stacked layer 11, the second contact layer 12, the first portion 11c of the second stacked layer 11, the active layer 13, the intermediate stacked layer 19, the first contact layer 15, and the first stacked layer 16, respectively. The stacked semiconductor layer 51e includes a semiconductor layer 51h having a high Al content for forming an aluminum oxide layer. Specifically, the stacked semiconductor layer 51 has structures as follows (expression “AlGaAs” represents binary GaAs and ternary AlGaAs). Stacked semiconductor layer for forming second stacked layer 11 that functions as lower distributed Bragg reflector (DBR)

### Thickness: 2000 to 10000 nm

Stacked layer for forming first portion 11c: Si-doped AlGaAs/AlGaAs super lattice structure
Stacked layer for forming second portion 11d: undoped AlGaAs/AlGaAs super lattice structure

### Semiconductor Layer for Forming Second Contact Layer 12

### Thickness: 300 to 600 nm

### Material: Si-doped AlGaAs

Dopant concentration: 1×10¹⁷ cm⁻³ or higher
Semiconductor layer for forming lower spacer layer 13d

### Thickness: 5 to 20 nm

Material: undoped AlGaAs

### Multi Quantum Well (MQW) Structure of Active Layer 13

### Thickness: 10 to 80 nm

Material: undoped InGaAs/GaAs multi quantum well (MQW) structure

### Semiconductor Layer for Forming Upper Spacer Layer 13c

### Thickness: 5 to 20 nm

Material: undoped AlGaAs

### Semiconductor Layer for Forming Intermediate Stacked Layer 19

### Semiconductor Layer to be Oxidized for Forming, for Example, Current Confinement Structure

### Thickness: 10 to 50 nm

### Material: Zn-doped or C-doped AlGaAs

A stacked semiconductor layer that serves as part of the upper distributed Bragg reflector (DBR) may be grown between the upper spacer layer 13c and the intermediate stacked layer 19. In the embodiment, a semiconductor layer that serves as part of the upper distributed Bragg reflector (DBR) is grown in the intermediate stacked layer 19.
Semiconductor layer that serves as part of upper distributed Bragg reflector (DBR) provided in intermediate stacked layer 19: Zn-doped or C-doped AlGaAs

### Thickness: 20 to 70 nm

Dopant concentration: 1×10¹⁷ cm⁻³ or higher

### Semiconductor Layer for Forming First Contact Layer 15

### Material: Zn-doped or C-doped AlGaAs

### Thickness: 40 to 90 nm

Dopant concentration: 1×10¹⁸ cm⁻³ or higher
Stacked semiconductor layer that serves as upper distributed Bragg reflector (DBR) provided in first stacked layer 16: undoped AlGaAs/AlGaAs super lattice structure AlGaAs that contacts the first contact layer 15 is Zn-doped or C-doped AlGaAs.

In step S102, as illustrated in FIG. 4B, a mask R1 for forming a semiconductor post is formed on a top surface of the stacked semiconductor layer 51 of the epitaxial substrate EP. The mask R1 is made of a resist, and has a relatively large thickness. Specifically, the resist is applied onto the top surface of the stacked semiconductor layer 51, and hence a resist film (for example, having a thickness of 2 micrometers) is formed. The resist film is exposed to light and developed. Then, the developed resist film is heat treated, and hence the mask R1 is obtained. The mask R1 has a pattern having protrusions. The protrusion of the mask R1 has, for example, a diameter of about 30 micrometers, at the bottom of the pattern of the mask R1.

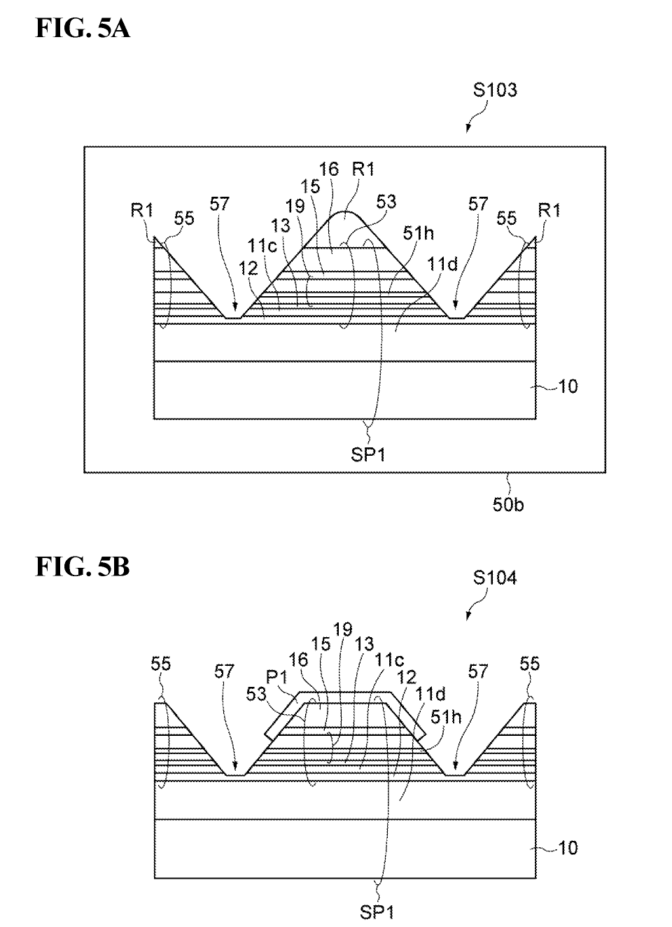

In step S103, as illustrated in FIG. 5A, the stacked semiconductor layer 51 is etched by using the mask R1, and a substrate product SP1 is obtained. Specifically, the epitaxial substrate EP with the mask R1 is disposed in an etching device 50b, for example, an inductive coupled plasma reactive ion etching (ICP-RIE) apparatus. Then, an etchant (etching gas) is supplied to the etching device 50b and etching is started. The etchant is, for example, boron trichloride (BCl₃). By the etching, both the mask R1 and the stacked semiconductor layer 51 are etched, and the pattern shape of the mask R1 is transferred to the stacked semiconductor layer 51. By the etching, a semiconductor post 53, a semiconductor terrace 55, and a groove 57 are formed. The stacked semiconductor layer 51 is etched so that the groove 57 reaches the semiconductor layer 51b for forming the second contact layer 12. The semiconductor layer 51b appears from the bottom of the groove 57 (having a bottom surface with a width of 4 micrometers). In the etching, the mask R1 is also etched, and the pattern shape of the mask R1 is changed during the etching. The etching is stopped before the mask R1 disappears. By the etching, the side surfaces of the semiconductor post 53 and the semiconductor terrace 55 may be inclined by a large inclination angle (for example, 75 degrees) with respect to the principal surface of the substrate 10. After the etching is completed, the residual mask R1 is removed, and the substrate product SP1 is obtained.

In step S104, as illustrated in FIG. 5B, after the mask R1 is removed, a protection mask P1 is formed on the substrate product SP1. The protection mask P1 is fabricated, for example, as follows. An inorganic insulating layer (for example, a SiN film having a thickness of 20 nm) for forming the protection mask P1 is deposited on the substrate product SP1. Then, a pattern is formed in the inorganic insulating layer by using a photolithography method and an etching method, and hence the protection mask P1 is obtained. The protection mask P1 has a pattern that covers the side surface of the first contact layer 15 that appears from the side surface of the semiconductor post 53. In the embodiment, the protection mask P1 covers the side surface of the first contact layer 15, and the side surface and the upper surface of the first stacked layer 16 on the first contact layer 15.

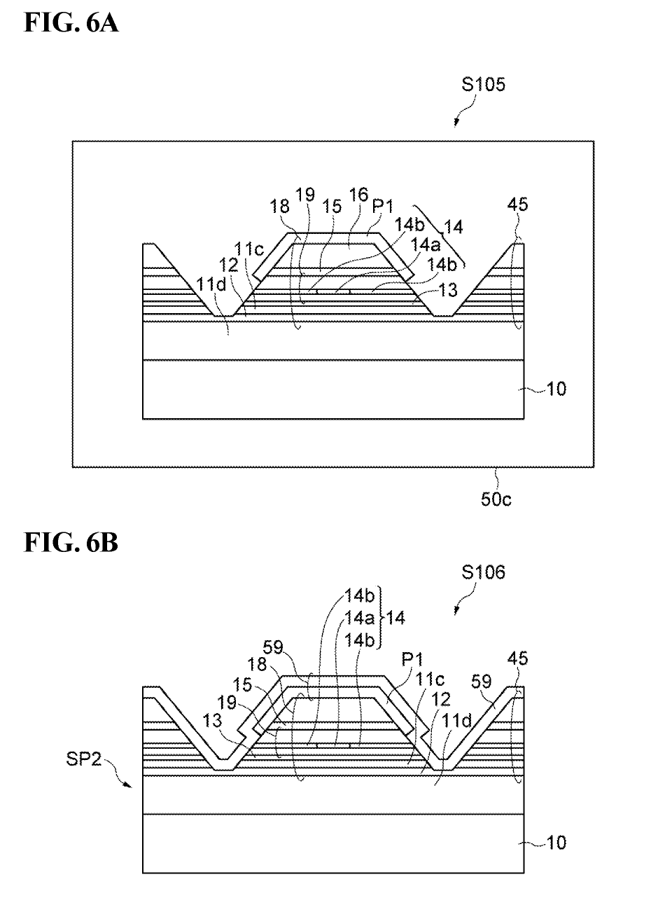

In step S105, as illustrated in FIG. 6A, the substrate product SP1 having the protection mask P1 is exposed to an oxidization atmosphere in an oxidization furnace 50c. The semiconductor layer 51h having the high Al content is oxidized from the side surface of the semiconductor post 53, and hence the current confinement structure 14 is formed. The oxidization atmosphere contains high-temperature steam at 350 degrees centigrade. By oxidizing the semiconductor post 53, the post 18 is formed from the semiconductor post 53. The semiconductor layer 51h having the high Al content is changed into the current confinement structure 14 having an insulating region of an oxide and a current aperture surrounded by the insulating region. The current aperture has a diameter, for example, in a range from 4 to 7.5 micrometers. In the embodiment, after the oxidizing step is ended, the protection mask P1 is left without being removed. If it is appropriate, the protection mask P1 may be removed.

In step S106, as illustrated in FIG. 6B, after the current confinement structure 14 is formed, an insulating layer 59 (for example, a Si(O)N film having a thickness of 20 nanometers or greater) is deposited on the entire surface of the substrate product SP1, and hence a substrate product SP2 is formed. In the following description, the protection mask P1 and the insulating layer 59 are not discriminated from each other and referenced as the insulating layer 59.

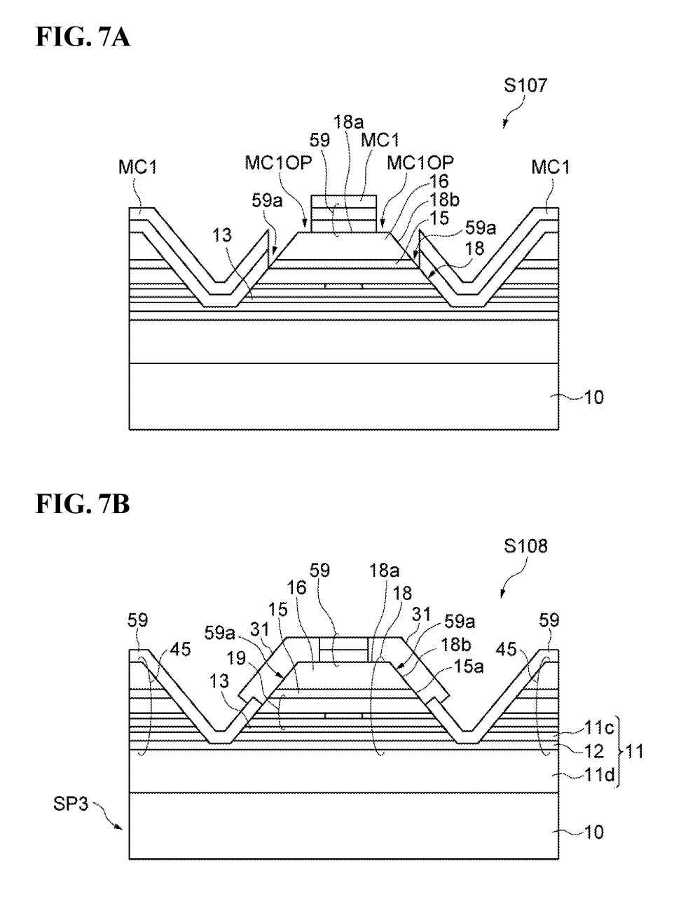

In step S107, as illustrated in FIG. 7A, after the current confinement structure 14 is formed, a first contact mask MC1 is formed on the substrate product SP2. The first contact mask MC1 contains, for example, a resist mask. The first contact mask MC1 defines an opening on the first contact layer 15. Specifically, the first contact mask MC1 has an opening MC1OP located on the side surface of the first contact layer 15 at the side surface 18b of the post 18. The insulating layer 59 is etched by using the first contact mask MC1, and hence an opening 59a is formed on the side surface 18b of the post 18, or specifically, on the side surface of the first contact layer 15. The side surface of the first contact layer 15 appears from the opening 59a. In the embodiment, the side surface of the first contact layer 15, and the entire side surface and a portion of the upper surface of the first stacked layer 16 appear from the opening 59a. To sufficiently form an opening on the side surface of the first contact layer 15, an edge of the opening MC1OP reaches the current confinement structure 14. However, the edge of the opening MC1OP is separated from the active layer 13 at the side surface 18b of the post 18. The first contact mask MC1 sufficiently covers the active layer 13. Also, the first contact mask MC1 sufficiently covers an emission area at the upper surface 18a of the post 18. Light is emitted from the emission area of the post 18 to the outside. The emission area is, for example, a region that is located on the outer side of the current aperture of the current confinement structure 14, and that has a diameter larger than the diameter of the current aperture by about 1 micrometer. After the etching of the insulating layer 59 is completed, the first contact mask MC1 is removed. If required, to form the opening 59a, the photolithography and etching processes are performed a plurality of times.

In step S108, as illustrated in FIG. 7B, after the opening 59a is formed in the insulating layer 59, the first electrode 31 is formed, and hence a substrate product SP3 is obtained. Specifically, a resist mask is formed for performing a lift-off process. The resist mask has an opening on the side surface of the first contact layer 15. A metal layer for forming the first electrode 31 is deposited, then the resist mask is removed, and hence the first electrode 31 is obtained. The metal layer contains, for example, titanium platinum gold (TiPtAu) having a thickness of 40 nanometers. In the embodiment, the first electrode 31 contacts the side surface of the first contact layer 15, the entire side surface and an outer area of the upper surface of the first stacked layer 16. The first electrode 31 has, for example, an opening in the upper surface 18a of the post 18. The opening is located on the outer side of the current aperture of the current confinement structure 14, and has a diameter larger than the diameter of the current aperture by about 1 micrometer.

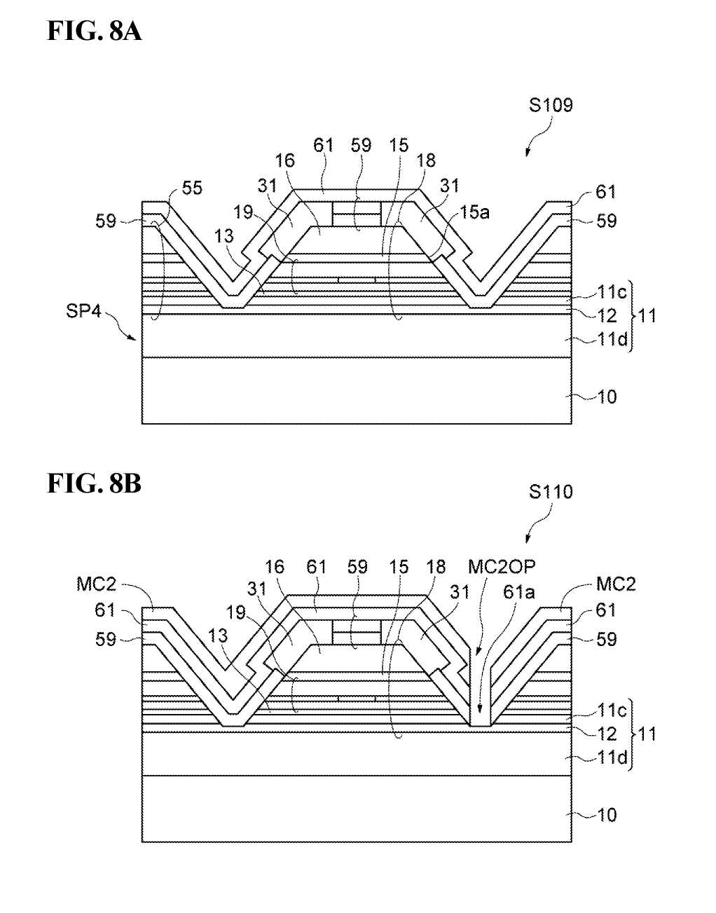

In step S109, as illustrated in FIG. 8A, an insulating layer 61 (for example, a Si(O)N film having a thickness of 20 nanometers or greater) is deposited on the entire surface of the substrate product SP3 so as to cover the first electrode 31, and hence a substrate product SP4 is formed.

In step S110, as illustrated in FIG. 8B, after the insulating layer 61 is formed, a second contact mask MC2 is formed on the substrate product SP4. The second contact mask MC2 contains, for example, a resist mask. The second contact mask MC2 defines an opening on the second contact layer 12. Specifically, the second contact mask MC2 has an opening MC2OP located on the upper surface of the second contact layer 12 in the groove 57 located on the outer side of the post 18. The insulating layers 59 and 61 are etched by using the second contact mask MC2, and hence an opening 61a is formed on the upper surface of the second contact layer 12. The upper surface of the second contact layer 12 appears from the opening 61a. After the etching of the insulating layer 61 is completed, the second contact mask MC2 is removed.

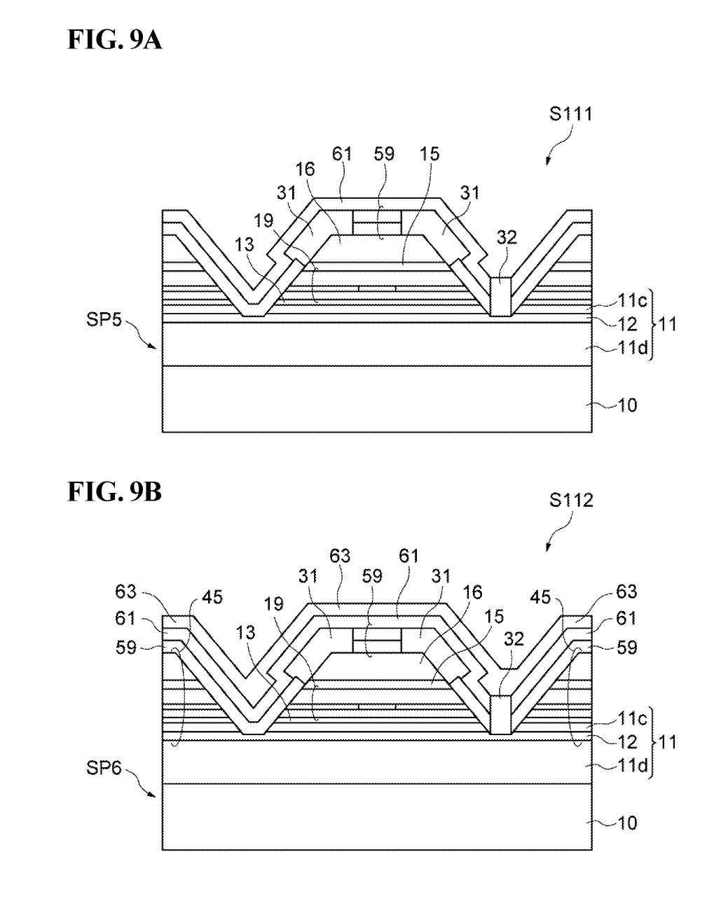

In step S111, as illustrated in FIG. 9A, after the opening 61a is formed in the insulating layer 61, the second electrode 32 is formed, and hence a substrate product SP5 is obtained. Specifically, a resist mask is formed for performing a lift-off process. The resist mask has an opening on the upper surface of the second contact layer 12 located at the bottom of the groove 57. A metal layer for forming the second electrode 32 is deposited, then the resist mask is removed, and hence the second electrode 32 is obtained. The metal layer contains, for example, TiPtAu having a thickness of 40 nanometers. In the embodiment, the second electrode 32 contacts the upper surface of the second contact layer 12.

In step S112, as illustrated in FIG. 9B, an insulating layer 63 (for example, a Si(O)N film having a thickness of 20 nanometers or greater) is deposited on the entire surface of the substrate product SP5 so as to cover the second electrode 32, and hence a substrate product SP6 is formed.

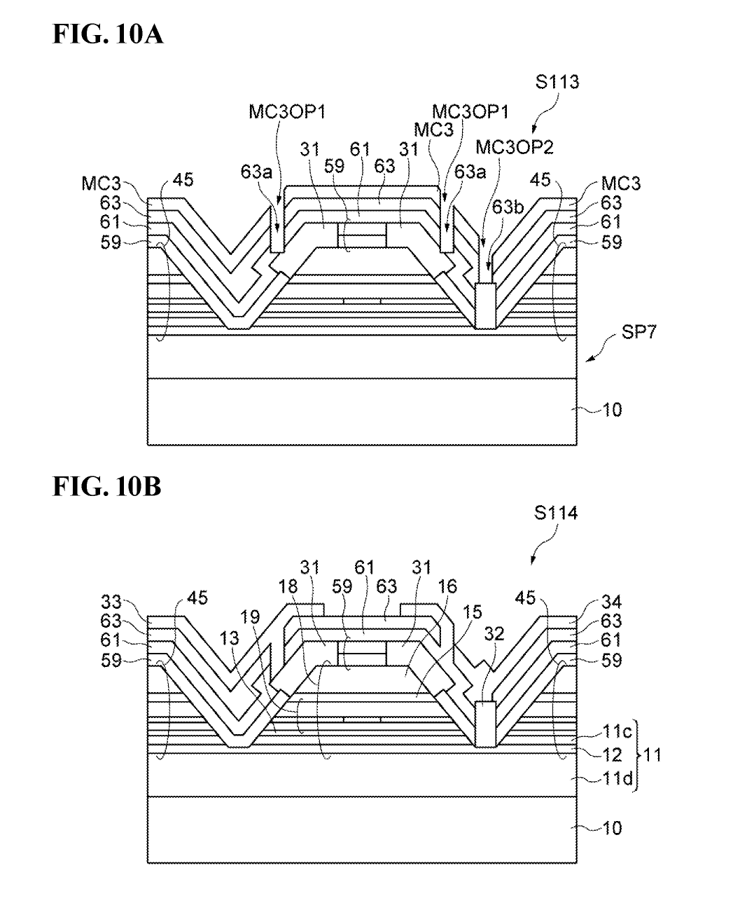

In step S113, as illustrated in FIG. 10A, after the insulating layer 63 is formed, a third contact mask MC3 is formed on the substrate product SP6. The third contact mask MC3 contains, for example, a resist mask. The third contact mask MC3 defines an opening on the first electrode 31 and an opening on the second electrode 32. Specifically, the third contact mask MC3 has an opening MC3OP1 located on the upper surface of the first electrode 31 on the side surface of the post 18, and an opening MC3OP2 located on the upper surface of the second electrode 32 in the groove 57 located on the outer side of the post 18. The insulating layers 59, 61, and 63 are etched by using the third contact mask MC3, and hence a first opening 63a is formed on the first electrode 31 and a second opening 63b is formed on the upper surface of the second electrode 32. The first electrode 31 and the second electrode 32 appear from the first opening 63a and the second opening 63b, respectively. After the first opening 63a and the second opening 63b are formed, the third contact layer MC3 is removed, and hence a substrate product SP7 is obtained.

In step S114, as illustrated in FIG. 10B, the first conductor 33 and the second conductor 34 are formed on the substrate product SP7. Specifically, a gold-based metal layer is deposited on the substrate product SP7 by using a mask. The first conductor 33 contacts the first electrode 31 through the first opening 63a. The second conductor 34 contacts the second electrode 32 through the second opening 63b. Metal is deposited by, for example, a sputtering method or an evaporation method. After the first conductor 33 and the second conductor 34 are formed, a passivation film (for example, a SiN film or a SiON film having a thickness of 120 nanometers) is formed.

Principles of the present invention have been described with reference to preferred embodiments and drawings. However, those skilled in the art understand that the present invention can be changed in arrangement and in details without departing from the principles. The present invention is not limited to the specific configurations disclosed in the embodiments. Therefore, the Claims and all the modifications and changes within the spirit of the Claims are claimed as the invention.

What is claimed is:

1. A surface-emitting laser comprising:
a substrate having a principal surface;
an active layer provided on the principal surface of the substrate;
a first stacked layer provided on the active layer, the first stacked layer serving as a first distributed Bragg reflector;
a first contact layer disposed between the active layer and the first stacked layer;
a post provided on the principal surface of the substrate, the post including the active layer, the first contact layer, and the first stacked layer, the post having an upper surface, a side surface, and a lower end; and
a first electrode that contacts the first contact layer at the side surface of the post.

2. The surface-emitting laser according to claim 1, further comprising:
an intermediate stacked layer provided between the first contact layer and the active layer,
wherein the first contact layer has a side surface that constitutes a portion of the side surface of the post, and
the side surface of the first contact layer extends from an edge at a boundary between the first contact layer and the first stacked layer to an edge at a boundary between the first contact layer and the intermediate stacked layer.

3. The surface-emitting laser according to claim 1, wherein the side surface of the post is widened out in a direction from the upper surface of the post toward the lower end of the post.

4. The surface-emitting laser according to claim 1, further comprising:
a second stacked layer provided between the substrate and the active layer, the second stacked layer including a second contact layer, the second stacked layer serving as a second distributed Bragg reflector; and
a second electrode that contacts the second contact layer,
wherein the lower end of the post is located in the second contact layer.

5. The surface-emitting laser according to claim 1, wherein the first stacked layer contains an undoped semiconductor.
